(19) United States
(12) Patent Application Publication
(10) Pub. No.: US 2025/0246509 A1
(43) Pub. Date: Jul. 31, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: HIROSHI ISHINO, Nisshin-shi (JP); RINTARO ASAI, Nisshin-shi (JP); MASAKI AOSHIMA, Nisshin-shi (JP); KOJI URAMOTO, Nisshin-shi (JP)

(21) Appl. No.: 19/016,201

(22) Filed: Jan. 10, 2025

(30) Foreign Application Priority Data
Jan. 30, 2024 (JP) 2024-011386

(51) Int. Cl. H01L 23/373; H01L 23/00; H01L 23/29; H01L 25/07

(52) U.S. Cl. CPC H01L 23/3735; H01L 23/293; H01L 24/24; H01L 25/072; H01L 2224/24137

(57) ABSTRACT

A semiconductor device includes first and second semiconductor chips, first and second heat sinks, a sealing member, a first wiring portion connected to the first semiconductor chip, a second wiring portion connected to the second semiconductor chip, a third wiring portion connecting the first and second semiconductor chips, and third and fourth heat sinks. The first and second semiconductor chips are configured to be controllable, allowing them to be turned on and off so that current flows in opposite directions in the first wiring portion and the second wiring portion. The first to third wiring portions are disposed on a side opposite to the first to fourth heat sinks with respect to the first and second semiconductor chips. The first and second wiring portions have portions facing each other. The third heat sink faces the first and second wiring portions, and the fourth heat sink faces the third wiring portion.

### CROSS REFERENCE TO RELATED APPLICATION

The present application claims the benefit of priority from Japanese Patent Application No. 2024-011386 filed on Jan. 30, 2024. The entire disclosures of the above application are incorporated herein by reference.

### TECHNICAL FIELD

The present disclosure relates to a semiconductor device having a first semiconductor chip and a second semiconductor chip.

### BACKGROUND

There is a semiconductor device having a first semiconductor chip and a second semiconductor chip. In the semiconductor device, for example, the first semiconductor chip is disposed on a first heat sink, and the second semiconductor chip is disposed on a second heat sink. The semiconductor device further has a first wiring portion connected to the first semiconductor chip, a second wiring portion connected to the second semiconductor chip, and a third wiring portion connected to the first and second semiconductor chips.

### SUMMARY

A semiconductor device according to an aspect includes: a first semiconductor chip and a second semiconductor chip each having a switching element; a first heat sink on which the first semiconductor chip is disposed; a second heat sink on which the second semiconductor chip is disposed; a sealing member made of a resin and sealing the first semiconductor chip and the second semiconductor chip; a first wiring portion connected to the first semiconductor chip; a second wiring portion connected to the second semiconductor chip; a third wiring portion connecting the first semiconductor chip and the second semiconductor chip; and a third heat sink and a fourth heat sink. The first semiconductor chip and the second semiconductor chip are configured to be controllable, allowing them to be turned on and off so that current flows in opposite directions in the first wiring portion and the second wiring portion. The first wiring portion, the second wiring portion, and the third wiring portion are collectively disposed on a side opposite to the first heat sink and the second heat sink with respect to the first semiconductor chip and the second semiconductor chip. The first wiring portion and the second wiring portion have portions facing each other. The third heat sink and the fourth heat sink that are disposed on a side opposite to the first wiring portion, the second wiring portion and the third wiring portion with respect to the first semiconductor chip and the second semiconductor chip. The third heat sink is disposed to face the first wiring portion and the second wiring portion, and the fourth heat sink is disposed to face the third wiring portion.

### BRIEF DESCRIPTION OF THE DRAWINGS

Objects, features and advantages of the present disclosure will become more apparent from the following detailed description made with reference to the accompanying drawings, in which:

FIG. 1 is a cross-sectional view of a semiconductor device according to a first embodiment;

FIG. 2 is a plan view of the semiconductor device shown in FIG. 1;

FIG. 3 is a diagram showing a circuit configuration of a first semiconductor chip and a second semiconductor chip of the semiconductor device;

FIG. 4 is a schematic cross-sectional view showing a current flowing in the semiconductor device;

FIG. 5 is a schematic plan view showing a current flowing in the semiconductor device;

FIG. 6 is a schematic plan view showing a current flowing in the semiconductor device;

FIG. 7 is a cross-sectional view of a semiconductor device according to a second embodiment;

FIG. 8 is a cross-sectional view of a semiconductor device according to a third embodiment;

FIG. 9A is a cross-sectional view of a semiconductor device according to another embodiment;

FIG. 9B is a cross-sectional view of a semiconductor device according to a further another embodiment; and

FIG. 9C is a cross-sectional view of a semiconductor device according to a still another embodiment.

### DETAILED DESCRIPTION

As a relevant technology, for example, there is a semiconductor device having a first semiconductor chip disposed on a first heat sink and a second semiconductor chip disposed on a second heat sink. The semiconductor device further has a first wiring portion connected to the first semiconductor chip, a second wiring portion connected to the second semiconductor chip, and a third wiring portion connected to the first and second semiconductor chips.

In the semiconductor device described above, heat generated in the first semiconductor chip is dissipated from the first heat sink, and heat generated in the second semiconductor chip is dissipated from the second heat sink. In the semiconductor device, however, the first wiring portion connected to the first semiconductor chip, the second wiring portion connected to the second semiconductor chip, and the third wiring portion connected to the first and second semiconductor chips also generate heat. For this reason, there is a demand to dissipate the heat from the first wiring portion, the second wiring portion, and the third wiring portion, thereby to suppress the first wiring portion, the second wiring portion, and the third wiring portion from overheating.

The present disclosure provides a semiconductor device capable of suppressing a first wiring portion, a second wiring portion, and a third wiring portion from overheating.

According to an aspect of the present disclosure, a semiconductor device includes: a first semiconductor chip formed with a switching element; a second semiconductor chip formed with a switching element; a first heat sink on which the first semiconductor chip is disposed; a second heat sink on which the second semiconductor chip is disposed; a sealing member made of a resin material and sealing the first semiconductor chip and the second semiconductor chip; a first wiring portion connected to the first semiconductor chip; a second wiring portion connected to the second semiconductor chip; and a third wiring portion connecting the first semiconductor chip and the second semiconductor chip. The first semiconductor chip and the second semiconductor chip are configured to be controllable, allowing them to be turned on and off so that current flows in opposite directions in the first wiring portion and the second wiring portion. The first wiring portion, the second wiring portion, and the third wiring portion are disposed collectively on a side opposite to the first heat sink and the second heat sink with respect to the first semiconductor chip and the second semiconductor chip. The first wiring portion and the second wiring portion have facing portions facing each other. The semiconductor device further includes a third heat sink and a fourth heat sink disposed on a side opposite to the first wiring portion, the second wiring portion and the third wiring portion with respect to the first semiconductor chip and the second semiconductor chip. The third heat sink is disposed to face the first wiring portion and the second wiring portion, and the fourth heat sink disposed to face the third wiring portion.

In the configuration described above, the third heat sink is disposed to face the first wiring portion as well as to face the second wiring portion. The fourth heat sink is disposed to face the third wiring portion. Therefore, heat that may be generated from the first to third wiring portions can be easily dissipated from the third heat sink and the fourth heat sink. Accordingly, it is less likely that the first to third wiring portions will be overheated.

Hereinafter, embodiments of the present disclosure will be described with reference to the drawings. In the following descriptions, the same or equivalent parts are denoted by the same reference numerals throughout the embodiments.

### First Embodiment

A first embodiment will be described with reference to the drawings. A semiconductor device of the present embodiment is, for example, mounted on a vehicle, and suitably used to control various electronic components.

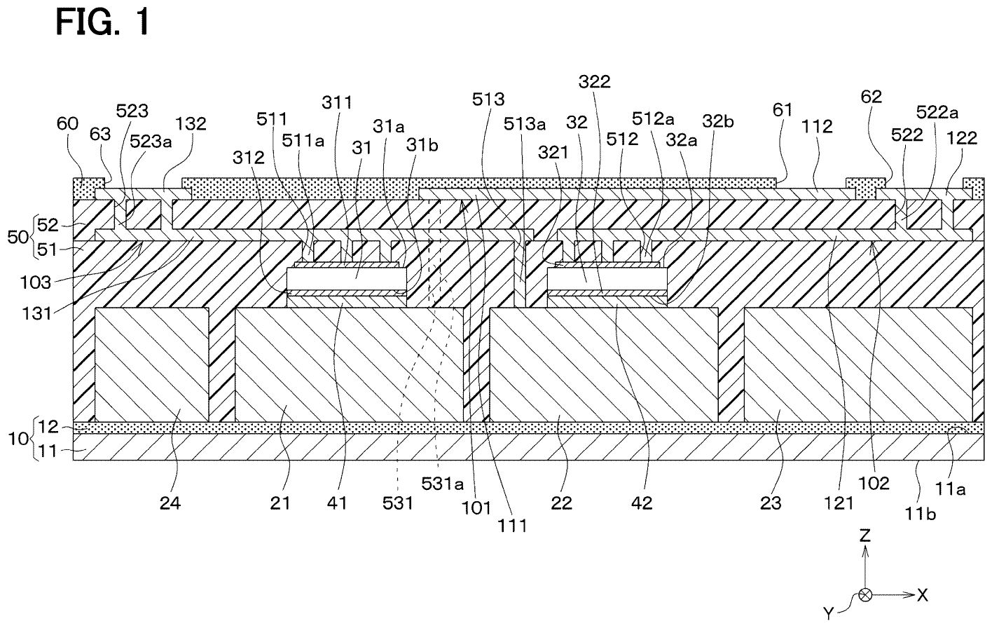

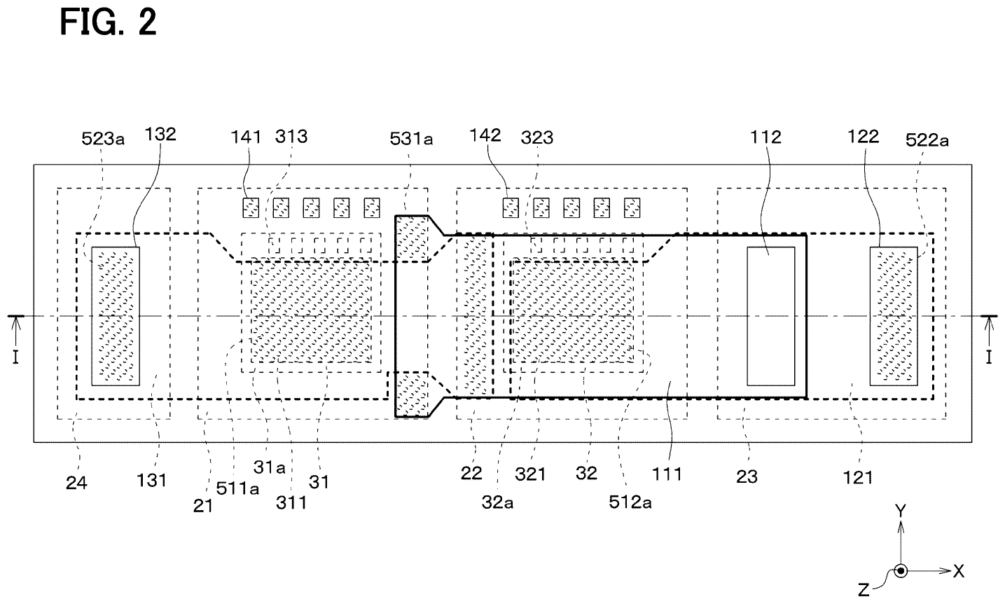

As shown in FIGS. 1 and 2, the semiconductor device includes an external connection heat sink 10, a first heat sink 21, a second heat sink 22, a third heat sink 23, a fourth heat sink 24, a first semiconductor chip 31, a second semiconductor chip 32, a sealing member 50, first to third wiring portions 101 to 103. FIG. 1 is a cross-sectional view taken along a line I-I in FIG. 2. Although FIG. 2 is a plan view of the semiconductor device shown in FIG. 1, illustration of a protective film 60, which will be described later, is omitted for ease of understanding.

The external connection heat sink 10 includes a main heat sink 11 and an insulating sheet 12. The main heat sink 11 is made of a copper plate or the like, and has a first surface 11a and a second surface 11b. The insulating sheet 12 is disposed adjacent to the first surface 11a of the main heat sink 11. When the semiconductor device is used to be mounted on a support member of a vehicle or the like, the second surface 11b of the main heat sink 11 is joined to the support member. The main heat sink 11 is made of, for example, a copper plate. The insulating sheet 12 is made of, for example, an epoxy resin.

In the following description of the present embodiment, a direction along a planar direction of the external connection heat sink 10 is defined as an X-axis direction, a direction perpendicular to the X-axis direction and along the planar direction of the external connection heat sink 10 is defined as a Y-axis direction, and a direction perpendicular to the X-axis direction and the Y-axis direction is defined as a Z-axis direction. For example, in FIG. 1, the horizontal direction is the X-axis direction, the direction perpendicular to the paper surface of FIG. 1 is the Y-axis direction, and the vertical direction is the Z-axis direction. The X-axis direction also corresponds to an arrangement direction of the first semiconductor chip 31 and the second semiconductor chip 32, as will be described later. The Z-axis direction also corresponds to a stacking direction of the first semiconductor chip 31 and the first heat sink 21 and a stacking direction of the second semiconductor chip 32 and the second heat sink 22, as will be described later.

The first to fourth heat sinks 21 to 24 are each in the form of a block made of copper or the like. In the present embodiment, the first to fourth heat sinks 21 to 24 each have a rectangular shape in a plan view. Also, the first to fourth heat sinks 21 to 24 have the same dimension (i.e., length) in the Y-axis direction. The first to fourth heat sinks 21 to 24 have the same dimension (i.e., thickness) in the Z-axis direction. Incidentally, the term “same” or “equal” herein includes slight manufacturing errors.

The first to fourth heat sinks 21 to 24 are arranged side by side on the insulating sheet 12 of the external connection heat sink 10. Specifically, the first to fourth heat sinks 21 to 24 are arranged in the X-axis direction in the following order: the fourth heat sink 24, the first heat sink 21, the second heat sink 22, and the third heat sink 23. In FIG. 1, the fourth heat sink 24, the first heat sink 21, the second heat sink 22, and the third heat sink 23 are arranged in this order from the left side of the paper to the right side of the paper in the X-axis direction.

The first semiconductor chip 31 and the second semiconductor chip 32 are each formed with a semiconductor element such as a switching element or a freewheeling diode element. Examples of the switching element include a metal oxide semiconductor field effect transistor (MOSFET) element and an insulated gate bipolar transistor (IGBT) element.

In the present embodiment, the first semiconductor chip 31 has a first electrode 311 on a first surface 31a and a second electrode 312 on a second surface 31b. The first semiconductor chip 31 is formed with the semiconductor element so as to cause a current to flow between the first electrode 311 and the second electrode 312. Moreover, the first semiconductor chip 31 has a plurality of pads 313 on the first surface 31a. The pads 313 include a gate pad that is connected to a gate electrode of the MOSFET element or the IGBT element. The pads 313 are shown in FIG. 2.

Similarly, the second semiconductor chip 32 has a first electrode 321 on a first surface 32a and a second electrode 322 on a second surface 32b. The second semiconductor chip 32 is formed with the semiconductor element so as to cause a current to flow between the first electrode 321 and the second electrode 322. Also, the second semiconductor chip 32 has a plurality of pads 323 on the first surface 32a. The pads 323 include a gate pad connected to a gate electrode of the MOSFET element or the IGBT element. The pads 323 are shown in FIG. 2.

The first semiconductor chip 31 is disposed on the first heat sink 21 through a first joining member 41. The second semiconductor chip 32 is disposed on the second heat sink 22 through a second joining member 42. That is, the first to fourth heat sinks 21 to 24 are disposed on the same side in the Z-axis direction with respect to the first semiconductor chip 31 and the second semiconductor chip 32. In FIG. 1, the first to fourth heat sinks 21 to 24 are disposed on the lower side of the first semiconductor chip 31 and the second semiconductor chip 32.

The first joining member 41 is made of a material that electrically and thermally connects the first semiconductor chip 31 and the first heat sink 21, and is made of, for example, solder or sintered silver. The second joining member 42 is made of a material that electrically and thermally connects the second semiconductor chip 32 and the second heat sink 22, and is made of, for example, solder or sintered silver. Since the first semiconductor chip 31 is disposed on the first heat sink 21 in this manner, heat generated from the first semiconductor chip 31 is dissipated from the first heat sink 21 to the external connection heat sink 10. Since the second semiconductor chip 32 is disposed on the second heat sink 22, heat generated from the second semiconductor chip 32 is dissipated from the second heat sink 22 to the external connection heat sink 10.

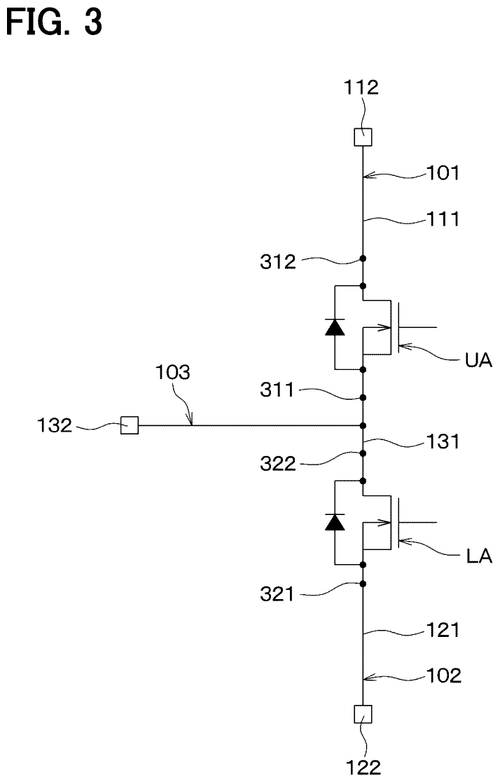

The first semiconductor chip 31 and the second semiconductor chip 32 of the present embodiment are used by being connected in series so as to configure an upper arm UA and a lower arm LA of an inverter circuit or the like. Specifically, as shown in FIG. 3, the first semiconductor chip 31 is used to form the upper arm UA. In this case, the second electrode 312 is connected to the first wiring portion 101 and the first electrode 311 is connected to the third wiring portion 103. The second semiconductor chip 32 is used to form the lower arm LA. In this case, the second electrode 322 is connected to the third wiring portion 103 and the first electrode 321 is connected to the second wiring portion 102. The first wiring portion 101 serves as a high-potential side wiring, so-called a P wiring, the second wiring portion 102 serves as a low-potential side wiring, so-called an N wiring, and the third wiring portion 103 serves as an output wiring, so-called an O wiring. Although not particularly shown, the third wiring portion 103 is connected to an external load or the like. In such a circuit configuration, the switching element of the first semiconductor chip 31 and the switching element of the second semiconductor chip 32 are alternately turned on. At the moment when the on state is switched, currents flow in opposite directions in the first wiring portion 101 and the second wiring portion 102.

As shown in FIG. 1, the sealing member 50 is disposed on the external connection heat sink 10 so as to seal the first semiconductor chip 31, the second semiconductor chip 32, the first heat sink 21, the second heat sink 22, the third heat sink 23, the fourth heat sink 24, and the like. In the present embodiment, the sealing member 50 is composed of a stack of film members made of resin, such as prepreg. The film member are integrated by being applied with heat and pressure. When the film members are heated and pressurized to be integrated, the resin material forming the film members flows into spaces between the first heat sink 21, the second heat sink 22, the third heat sink 23, and the fourth heat sink 24, so that the sealing member 50 is positioned between the first heat sink 21, the second heat sink 22, the third heat sink 23, and the fourth heat sink 24.

In the following description of the present embodiment, the portion of the sealing member 50 that is disposed on the insulating sheet 12 and seals the first and second semiconductor chips 31 and 32 and the first to fourth heat sinks 21 to 24 will be described as a first sealing member 51, and the portion of the sealing member 50 that is disposed on the first sealing member 51 will be described as a second sealing member 52.

The first to third wiring portions 101 to 103 are appropriately disposed on the first sealing member 51 or the second sealing member 52 so that the first semiconductor chip 31 and the second semiconductor chip 32 form the upper arm UA and the lower arm LA, respectively. That is, in the present embodiment, the first to third wiring portions 101 to 103 are collectively disposed on the same side (i.e., the upper side in FIG. 1) with respect to first semiconductor chip 31 and second semiconductor chip 32. The first to third wiring portions 101 to 103 are made of, for example, aluminum wirings or copper wirings.

Specifically, the first sealing member 51 is formed with a first chip via hole 511 to expose the first electrode 311 of the first semiconductor chip 31. The first sealing member 51 is formed with a second chip via hole 512 to expose the first electrode 321 of the second semiconductor chip 32. The first sealing member 51 is formed with a second heat sink via hole 513 to expose a portion of the second heat sink 22 adjacent to the first heat sink 21. Each of the via holes 511 to 513 is formed at multiple locations.

The third wiring portion 103 has a wiring layer 131 (hereinafter referred to as the third wiring portion wiring layer 131). The third wiring portion wiring layer 131 is disposed on the first sealing member 51 so as to face the fourth heat sink 24, the first heat sink 21, the first semiconductor chip 31, and a portion of the second heat sink 22 that is adjacent to the first heat sink 21. The third wiring portion wiring layer 131 is connected to the first electrode 311 of the first semiconductor chip 31 through first chip vias 511a that are disposed in the first chip via holes 511. In addition, the third wiring portion wiring layer 131 is connected to the second heat sink 22 through a second heat sink via 513a disposed in the second heat sink via hole 513, and is connected to the second electrode 322 of the second semiconductor chip 32 through the second heat sink 22. The first chip via 511a and the second heat sink via 513a are each made of, for example, a copper via. Similarly, each via, which will be described later, is also made of a copper via or the like.

In the present embodiment, the third wiring portion wiring layer 131 has a generally rectangular shape in the plan view with its longitudinal direction in the X-axis direction. In a section in which the third wiring portion wiring layer 131 overlaps with a wiring layer 111 of the first wiring portion 101 (hereinafter referred to as the first wiring portion wiring layer 111). in the Z-axis direction, the length of the third wiring portion wiring layer 131 in the Y-axis direction is shorter than that of the first wiring portion wiring layer 111. Moreover, the third wiring portion wiring layer 131 is formed so as not to overlap with the pads 313 of the first semiconductor chip 31 in the Z-axis direction. Note that, the phrase “in the Z-axis direction” can be regarded as when viewed in the Z-axis direction.

The second wiring portion 102 has a wiring layer 121 (hereinafter referred to as the second wiring portion wiring layer 121) disposed on the first sealing member 51 so as to face the third heat sink 23, the second heat sink 22, and the second semiconductor chip 32. The second wiring portion wiring layer 121 is connected to the first electrode 321 of the second semiconductor chip 32 through second chip vias 512a that are disposed in the second chip via holes 512.

The second wiring portion wiring layer 121 of the present embodiment has a generally rectangular shape in the plan view, with the X-axis direction as the longitudinal direction. The second wiring portion wiring layer 121 is disposed such that an end portion on the side opposite to the second semiconductor chip 32 in the X-axis direction protrudes from the first wiring portion wiring layer 111 described later. Moreover, the second wiring portion wiring layer 121 is disposed so as not to overlap with the pads 323 of the second semiconductor chip 32 in the Z-axis direction.

The second sealing member 52 is disposed on the first sealing member 51 so as to cover the third wiring portion wiring layer 131 and the second wiring portion wiring layer 121. The second sealing member 52 is formed with a third wiring portion via hole 523 to expose a portion of the third wiring portion wiring layer 131 that faces the fourth heat sink 24. Further, the second sealing member 52 is formed with a second wiring portion via hole 522 to expose a portion of the second wiring portion wiring layer 121 that faces the third heat sink 23.

The first sealing member 51 and the second sealing member 52 are each formed with a first heat sink via hole 531 to expose a portion of the first heat sink 21 adjacent to the second heat sink 22. Each of the via holes 522, 523, and 531 is formed at plural locations.

The first wiring portion 101 has a first wiring portion wiring layer 111 disposed on the second sealing member 52 so as to face the third heat sink 23, the second semiconductor chip 32, and the portion of the first heat sink 21, the portion being adjacent to the second heat sink 22. Specifically, the first wiring portion wiring layer 111 is disposed so as to face the second wiring portion wiring layer 121 as well as the portion of the first heat sink 21 adjacent to the second heat sink 22. In other words, the first wiring portion wiring layer 111 has a portion that is located on a side opposite to the third heat sink 23 with respect to the second wiring portion wiring layer 121.

The first wiring portion wiring layer 111 has a generally rectangular shape in the plan view with its longitudinal direction in the X-axis direction. The first wiring portion wiring layer 111 is formed such that both ends of a section that faces the first heat sink 21 protrude from the third wiring portion wiring layer 131 in the Y-axis direction. In other words, the first wiring portion wiring layer 111 has a non-overlapping portion that does not face the third wiring portion wiring layer 131 in the section that faces the first heat sink 21. Furthermore, in the protruding portion, the first wiring portion wiring layer 111 is connected to the first heat sink 21 through the first heat sink via 531a disposed in the via first heat sink hole 531, and is thus connected to the second electrode 312 of the first semiconductor chip 31 through the first heat sink 21.

On the second sealing member 52, a first terminal portion 112 constituting the first wiring portion 101, a second terminal portion 122 constituting the second wiring portion 102, and a third terminal portion 132 constituting the third wiring portion 103 are disposed. The third terminal portion 132 is disposed so as to face the fourth heat sink 24 in the Z-axis direction, and is connected to the third wiring portion wiring layer 131 through a third wiring portion via 523a disposed in the third wiring portion via hole 523 formed in the second sealing member 52.

The second terminal portion 122 is disposed to face the third heat sink 23, and is connected to the second wiring portion wiring layer 121 through a second wiring portion via 522a disposed in the second wiring portion via hole 522 formed in the second sealing member 52.

The first terminal portion 112 is configured as a part of the first wiring portion wiring layer 111, and is configured as a portion facing the third heat sink 23. In the present embodiment, the first terminal portion 112, the second terminal portion 122, and the third terminal portion 132 are arranged in the X-axis direction in the order of the third terminal portion 132, the first terminal portion 112, and the second terminal portion 122. More specifically, the first and second semiconductor chips 31, 32 and the first to third terminal portions 112 to 132 are arranged along the X-axis direction in the following order: the third terminal portion 132, the first semiconductor chip 31, the second semiconductor chip 32, the first terminal portion 112, and the second terminal portion 122, in the Z-axis direction, that is, when viewed in the Z-axis direction.

A protective film 60 made of a solder resist or the like is disposed on the second sealing member 52. The protective film 60 is formed with a contact hole 61 exposing the first terminal portion 112, a contact hole 62 exposing the second terminal portion 122, and a contact hole 63 exposing the third terminal portion 132.

In addition, first signal terminal portions 141 connected to the pads 313 of the first semiconductor chip 31, and second signal terminal portions 142 connected to the pads 323 of the second semiconductor chip 32 are disposed on the second sealing member 52. Although not specifically shown, the pads 313 of the first semiconductor chip 31 and the first signal terminal portions 141 are electrically connected through connection wiring layers disposed on the first sealing member 51 and connection vias disposed in the first sealing member 51 and the second sealing member 52. Similarly, the pads 323 of the second semiconductor chip 32 and the second signal terminal portions 142 are electrically connected through connection wiring layers disposed on the first sealing member 51 and connection vias disposed in the first sealing member 51 and the second sealing member 52. The first signal terminal portions 141 and the second signal terminal portions 142 are disposed so as to be exposed from the contact holes formed in the protective film 60.

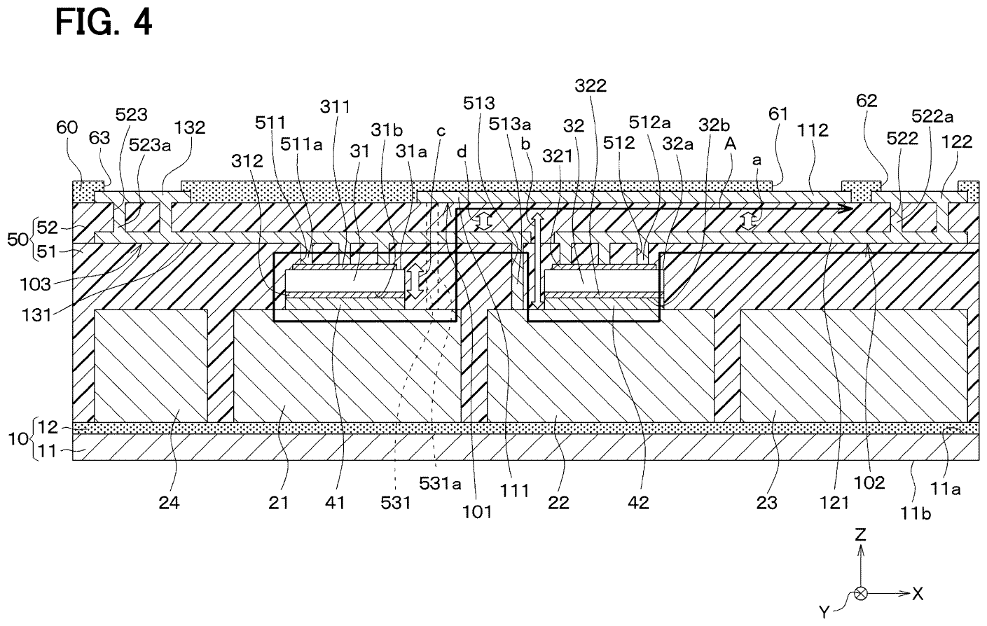

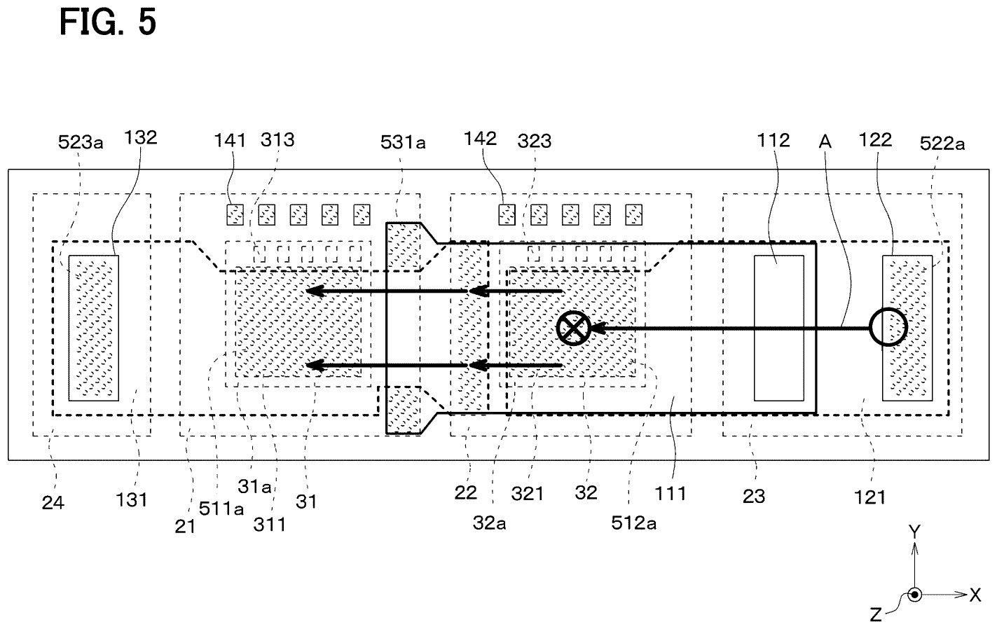

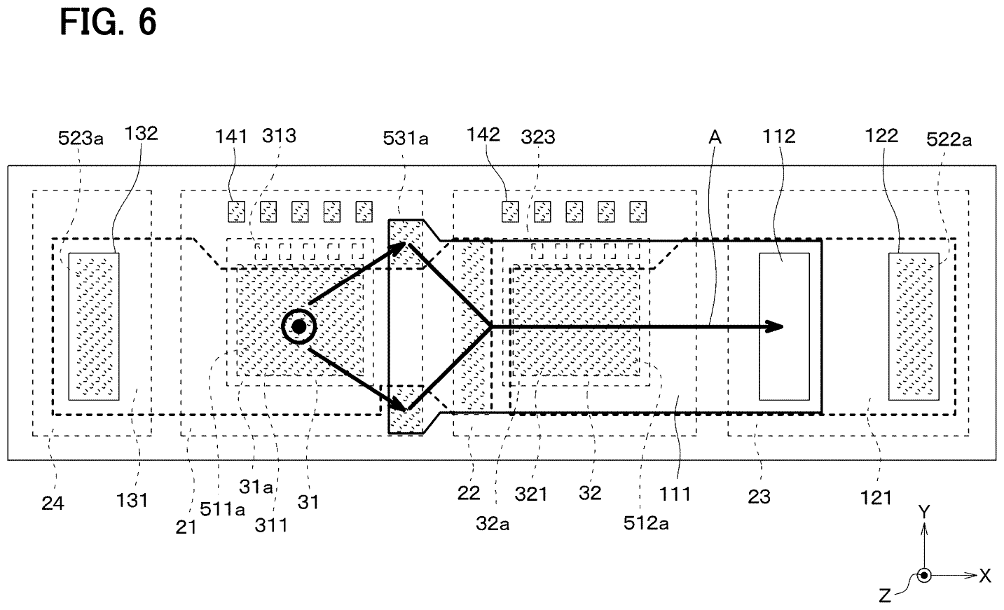

The configuration of the semiconductor device according to the present embodiment has been described above. In such a semiconductor device, as described above, the switching elements of the first semiconductor chip 31 and the second semiconductor chip 32 are alternately turned on. As shown in FIGS. 4 to 6, at the moment when the on state switches, a current flows as shown by a solid arrow A. At this time, in the present embodiment, since the first to third wiring portions 101 to 103 are disposed as described above, it is possible to reduce impedance. In FIG. 5, the arrow A indicates the current flowing from the second terminal portion 122 to the first semiconductor chip 31. In FIG. 6, the arrow A indicates the current flowing from the first semiconductor chip 31 to the first terminal portion 112.

Specifically, in the portions indicated by a blank arrow a in FIG. 4, the first wiring portion wiring layer 111 and the second wiring portion wiring layer 121 are disposed so as to face each other. Therefore, in this portion, the current flow direction in the first wiring portion wiring layer 111 is opposite to the current flow direction in the second wiring portion wiring layer 121, so the impedance between the first wiring portion wiring layer 111 and the second wiring portion wiring layer 121 reduces.

In the portion indicated by a blank arrow b, the first wiring portion wiring layer 111 and the second heat sink 22 are disposed to face each other. Therefore, in this portion, the current flow direction in the first wiring portion wiring layer 111 and the current flow direction in the second heat sink 22 are opposite, so the impedance between the first wiring portion wiring layer 111 and the second heat sink 22 reduces.

In the portion indicated by a blank arrow c, the third wiring portion wiring layer 131 and the first heat sink 21 are disposed to face each other. Therefore, in this portion, the current flow direction in the third wiring portion wiring layer 131 and the current flow direction in the first heat sink 21 are opposite, so the impedance between the third wiring portion wiring layer 131 and the first heat sink 21 reduces.

In the portion indicated by a blank arrow d, the first wiring portion wiring layer 111 and the third wiring portion wiring layer 131 are disposed to face each other. Therefore, in this portion, the current flow direction in the first wiring portion wiring layer 111 and the current flow direction in the third wiring portion wiring layer 131 are opposite, so the impedance between the first wiring portion wiring layer 111 and the third wiring portion wiring layer 131 reduces.

In the present embodiment, the semiconductor device has the third heat sink 23 and the fourth heat sink 24 in addition to the first heat sink 21 on which the first semiconductor chip 31 is disposed and the second heat sink 22 on which the second semiconductor chip 32 is disposed. Specifically, the third heat sink 23 is disposed so as to face the first wiring portion wiring layer 111 and the first terminal portion 112, and is also disposed so as to face the second wiring portion wiring layer 121 and the second terminal portion 122. The fourth heat sink 24 is disposed so as to face the third wiring portion wiring layer 131 and the third terminal portion 132. Therefore, heat that may be generated in the first to third wiring portions 101 to 103 can be easily dissipated from the third heat sink 23 and the fourth heat sink 24. As such, it is possible to suppress the first to third wiring portions 101 to 103 from overheating.

According to the present embodiment described above, the third heat sink 23 is disposed so as to face the first wiring portion wiring layer 111 and the first terminal portion 112, and is also disposed so as to face the second wiring portion wiring layer 121 and the second terminal portion 122. The fourth heat sink 24 is disposed so as to face the third wiring portion wiring layer 131 and the third terminal portion 132. Therefore, heat that may be generated in the first to third wiring portions 101 to 103 can be easily dissipated from the third heat sink 23 and the fourth heat sink 24. As such, it is possible to suppress the first to third wiring portions 101 to 103 from overheating. In addition, the first to fourth heat sinks 21 to 24 are disposed on the same side relative to the first and second semiconductor chips 31 and 32, and the first to third wiring portions 101 to 103 are disposed collectively on the opposite side to the first to fourth heat sinks 21 to 24, with respect to the first and second semiconductor chips 31 and 32. Therefore, it is possible to suppress the arrangement from becoming complicated.

(1) In the present embodiment, the first to fourth heat sinks 21 to 24 have the same thickness. Therefore, when forming the sealing member 50, the flowability of the resin material forming the sealing member 50 is less likely to vary, and variation in quality can be suppressed.

(2) In the present embodiment, when viewed in the Z-axis direction, the first and second semiconductor chips 31 and 32 and the first to third terminal portions 112 to 132 are arranged in the following order along the X-axis direction: the third terminal portion 132, the first semiconductor chip 31, the second semiconductor chip 32, the first terminal portion 112, and the second terminal portion 122. This makes it possible to easily route the first to third wiring portions 101.

(3) In the present embodiment, the first wiring portion wiring layer 111 and the third wiring portion wiring layer 131 are configured so that the first wiring portion wiring layer 111 has the non-overlapping portion that does not overlap with the third wiring portion wiring layer 131 in the section above the first heat sink 21. The first wiring portion wiring layer 111 is connected to the first heat sink 21 at the non-overlapping portion. Therefore, the first wiring portion wiring layer 111 and the first heat sink 21 can be easily connected to each other.

(4) In the present embodiment, the first wiring portion wiring layer 111 is configured to have the portion located on the opposite side to the third heat sink 23 with respect to the second wiring portion wiring layer 121. In this case, it is possible to ease routing of the first wiring portion 101 and the second wiring portion 102 when the third terminal portion 132, the first semiconductor chip 31, the second semiconductor chip 32, the first terminal portion 112, and the second terminal portion 122 are arranged in this order along the X-axis direction.

### Second Embodiment

The following describes a second embodiment of the present disclosure. In the present embodiment, the number of the first semiconductor chips 31 and the number of the second semiconductor chips 32 are changed from those in the first embodiment. The other configurations of the present embodiment are similar to those of the first embodiment, and therefore a description of the similar configurations will not be repeated.

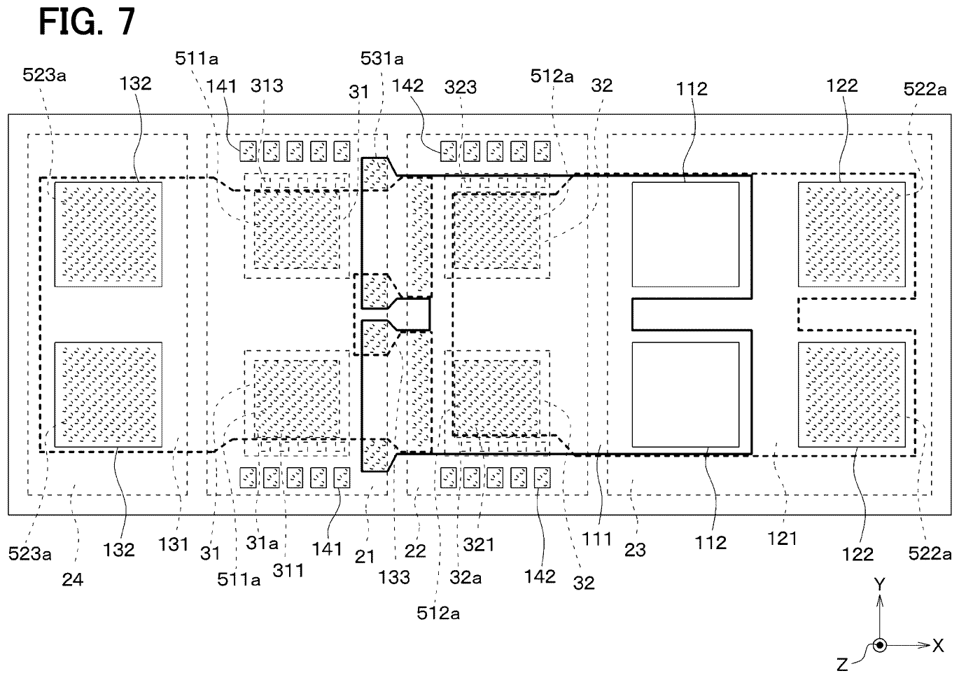

As shown in FIG. 7, the semiconductor device of the present embodiment includes two first semiconductor chips 31, each of which is disposed on the first heat sink 21. In the present embodiment, the two first semiconductor chips 31 are disposed on the first heat sink 21 so as to be adjacent to each other in the Y-axis direction.

Similarly, the semiconductor device includes two second semiconductor chips 32, each of which is disposed on the second heat sink 22. In the present embodiment, the two second semiconductor chips 32 are disposed on the second heat sink 22 so as to be adjacent to each other in the Y-axis direction.

In the present embodiment, the two first semiconductor chips 31 are connected in parallel to form one upper arm UA, and the two second semiconductor chips 32 are connected in parallel to form one lower arm LA.

The length of the first heat sink 21 in the Y-axis direction is adjusted so that the two first semiconductor chips 31 can be arranged side by side in the Y-axis direction thereon. Similarly, the length of the second heat sink 22 in the Y-axis direction is adjusted so that the two second semiconductor chips 32 can be arranged side by side in the Y-axis direction thereon.

In the present embodiment, the third heat sink 23 and the fourth heat sink 24 have the same length in the Y-axis direction as the first heat sink 21 and the second heat sink 22.

The third wiring portion wiring layer 131 is disposed so as to face the two first semiconductor chips 31. However, in the present embodiment, the third wiring portion wiring layer 131 has a recess portion 133 at approximately the center in the Y-axis direction at the end portion adjacent to the first semiconductor chip 31 in the X-axis direction. Therefore, in the section where the first wiring portion wiring layer 111 faces the first heat sink 21, the portion that is located within the recess portion 133 is the non-overlapping portion that does not overlap with the third wiring portion wiring layer 131 in the Z-axis direction.

The second wiring portion wiring layer 121 is disposed so as to face the two second semiconductor chips 32.

The first wiring portion wiring layer 111 is disposed so as to face the two second semiconductor chips 32. Similar to the first embodiment described above, the first wiring portion wiring layer 111 is connected to the first heat sink 21 through the first heat sink via 531a in the portion that faces the first heat sink 21 and protrudes in the Y-axis direction from the third wiring portion wiring layer 131. In addition, the first wiring portion wiring layer 111 is connected to the first heat sink 21 through the first heat sink via 531a in the section that faces the portion of the third wiring portion wiring layer 131 in which the recess portion 133 is formed. In other words, the first wiring portion wiring layer 111 of the present embodiment is connected to the first heat sink 21 also at the central portion in the Y-axis direction. Thus, as compared to the first embodiment described above, the number of the connection points of the first wiring portion wiring layer 111 with the first heat sink 21 is larger than that of the first embodiment.

That is, in the present embodiment, as described above, the length of the first heat sink 21 in the Y-axis direction is longer than that in the first embodiment. For this reason, by increasing the number of connection points between the first wiring portion wiring layer 111 and the first heat sink 21, it becomes easier to stabilize the potential of the first heat sink 21.

In addition, in the present embodiment, since the length of the semiconductor device in the Y-axis direction is longer than that in the first embodiment described above, the semiconductor device has two first terminal portions 112, two second terminal portions 122, and two third terminal portions 132 in order to improve connectivity with an external circuit. When the semiconductor device is connected to an external circuit, one of the two first terminal portions 112, one of the two second terminal portions 122, and one of the two third terminal portions 132 are connected to the external circuit. Alternatively, in the semiconductor device, both of the two first terminal portions 112, both of the two second terminal portions 122, and both of the two third terminal portions 132 may be connected to an external circuit.

As described above, also in the semiconductor device having the two first semiconductor chips 31 and the two second semiconductor chips 32, the similar effects to those in the first embodiment can be achieved.

### Third Embodiment

The following describes a third embodiment of the present disclosure. In the present embodiment, the number of the first semiconductor chip 31 and the number of the second semiconductor chip 32 are changed from those in the second embodiment. The other configurations of the present embodiment are similar to those of the second embodiment, and therefore a description of the similar configurations will not be repeated.

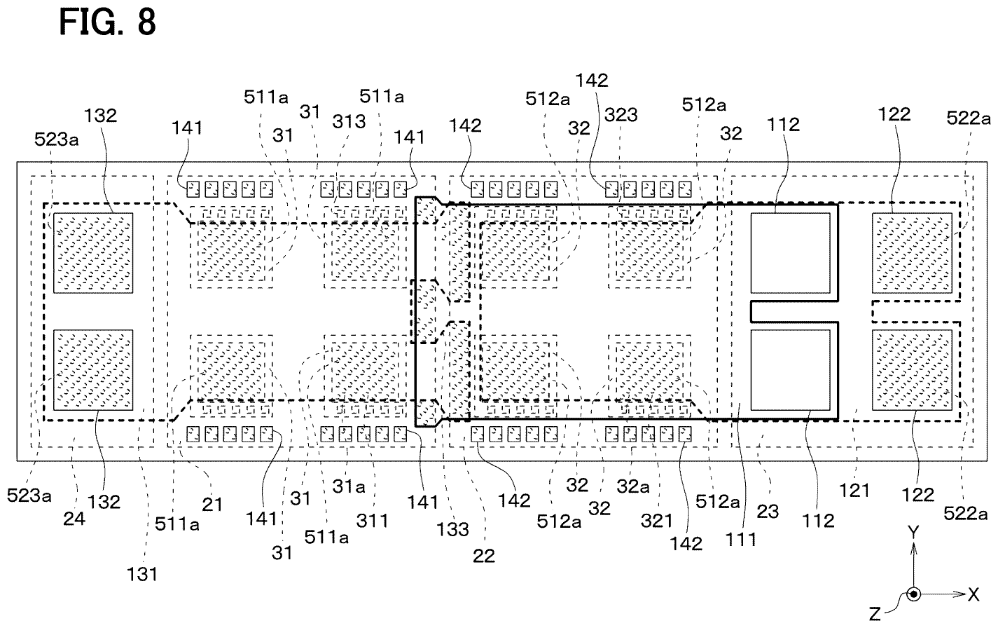

As shown in FIG. 8, the semiconductor device of the present embodiment includes four first semiconductor chips 31, each of which is disposed on the first heat sink 21. In the present embodiment, the four first semiconductor chips 31 are disposed on the first heat sink 21 such that two of which are adjacent to each other in the X-axis direction and the Y-axis direction.

Similarly, the semiconductor device includes four second semiconductor chips 32, each of which is disposed on the second heat sink 22. In the present embodiment, the four second semiconductor chips 32 are disposed on the second heat sink 22 such that two of which are adjacent to each other in the X-axis direction and the Y-axis direction.

In the present embodiment, the four first semiconductor chips 31 are connected in parallel to form one upper arm UA, and the four second semiconductor chips 32 are connected in parallel to form one lower arm LA.

Furthermore, as compared to the second embodiment described above, since the two first semiconductor chips 31 are arranged in the X-axis direction, the length of the first heat sink 21 in the X-axis direction is longer than that of the first heat sink 21 in the second embodiment. Similarly, since the two second semiconductor chips 32 are arranged in the X-axis direction, the length of the second heat sink 22 in the X-axis direction is longer than that of the second heat sink 22 in the second embodiment.

The lengths of the first wiring portion wiring layer 111, the second wiring portion wiring layer 121, and the third wiring portion wiring layer 131 in the X-axis direction are adjusted to correspond to the shapes of the first heat sink 21 and the second heat sink 22.

As described above, also in the semiconductor device having the four first semiconductor chips 31 and the four second semiconductor chips 32, the similar effects to those in the first embodiment described above can be achieved.

### Other Embodiments

Although the present disclosure has been described in accordance with the embodiments, it is understood that the present disclosure is not limited to the embodiments or the structures. The present disclosure includes various modification examples and modifications within the equivalent scope. In addition, various combinations and configurations, as well as other combinations and configurations that include only one element, more, or less, fall within the scope and spirit of the present disclosure.

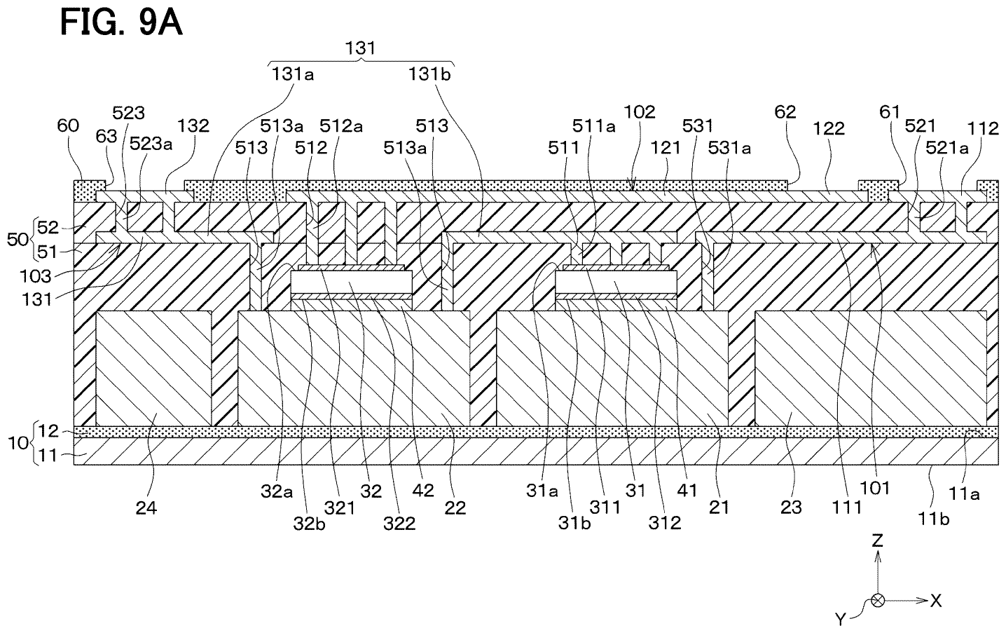

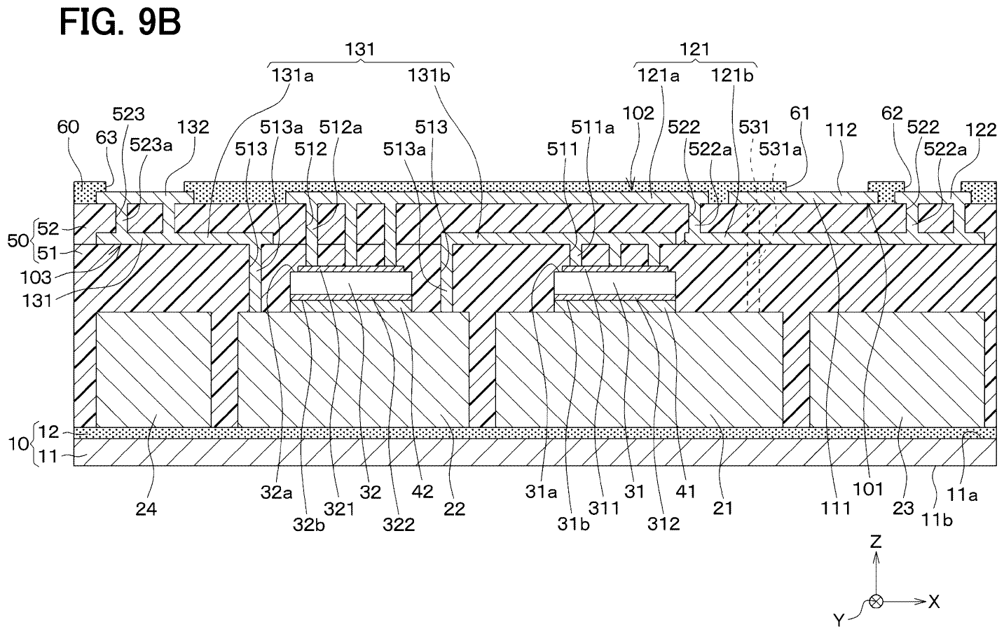

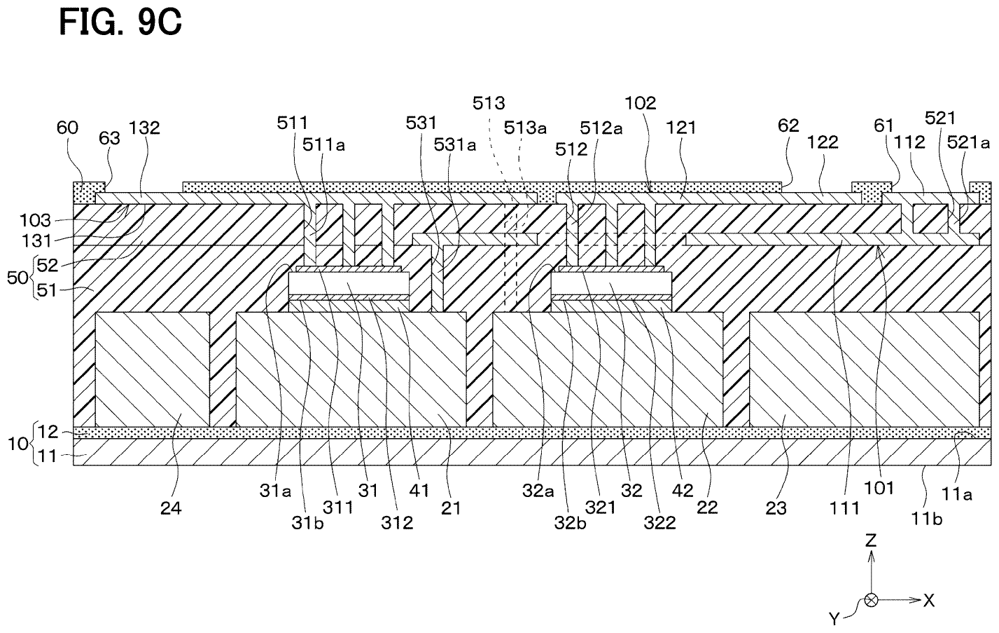

For example, in the first embodiment described above, the arrangement locations of the first to third wiring portions 101 to 103 and the like can be changed as appropriate as long as the fourth heat sink 24 is disposed to face the third wiring portion 103, and the third heat sink 23 is disposed to face the first wiring portion 101 and the second wiring portion 102. For example, the semiconductor device may have the configurations shown in FIGS. 9A to 9C.

In the semiconductor device shown in FIG. 9A, the pair of the first semiconductor chip 31 and the first heat sink 21, and the pair of the second semiconductor chip 32 and the second heat sink 22 are arranged in an opposite manner to those of the first embodiment. That is, in the semiconductor device shown in FIG. 9A, the fourth heat sink 24, the second heat sink 22, the first heat sink 21, and the third heat sink 23 are arranged in this order along the X-axis direction.

In this semiconductor device, the third wiring portion wiring layer 131 has a first wiring layer 131a (hereinafter referred to as the third wiring portion first wiring layer 131a) disposed in a position facing the fourth heat sink 24 and the portion of the second heat sink 22 adjacent to the fourth heat sink 24 on the first sealing member 51. In addition, the third wiring portion wiring layer 131 has a second wiring layer 131b (hereinafter referred to as the third wiring portion second wiring layer 131b) disposed in a position facing the portion of the second heat sink 22 adjacent to the first heat sink 21, a position facing the portion of the first heat sink 21 adjacent to the second heat sink 22, and a position facing the portion of the first semiconductor chip 31, on the first sealing member 51. On the first sealing member 51, the third wiring portion first wiring layer 131a and the third wiring portion second wiring layer 131b are formed separately.

The third wiring portion first wiring layer 131a and the third wiring portion second wiring layer 131b are each connected to the second heat sink 22 through the second heat sink via 513a formed in the first sealing member 51. The third wiring portion first wiring layer 131a is connected to the third terminal portion 132 through the third wiring portion via 523a formed in the second sealing member 52. The third wiring portion second wiring layer 131b is connected to the first electrode 311 of the first semiconductor chip 31 through the first chip via 511a formed in the first sealing member 51.

The first wiring portion wiring layer 111 and the second wiring portion wiring layer 121 are disposed such that the first wiring portion wiring layer 111 is located on the first sealing member 51 and the second wiring portion wiring layer 121 is located on the second sealing member 52. In other words, the arrangement relationship between the first wiring portion wiring layer 111 and the second wiring portion wiring layer 121 is reversed from that of the first embodiment described above. The first wiring portion wiring layer 111 is connected to the first heat sink 21 through the first heat sink via 531a formed in the first sealing member 51. The first wiring portion wiring layer 111 is connected to the first terminal portion 112 through the first wiring portion via 521a formed in the second sealing member 52.

The second wiring portion wiring layer 121 is connected to the first electrode 321 of the second semiconductor chip 32 through the second chip vias 512a formed in the first and second sealing members 51 and 52. In this semiconductor device, the second terminal portion 122 is provided by a part of the second wiring portion wiring layer 121.

Even when the first to third wiring portions 101 to 103 are arranged in the manner as described above, the circuit configuration shown in FIG. 3 can be realized, and the similar effects to those in the first embodiment can be achieved.

In the semiconductor device shown in FIG. 9B, similar to the semiconductor device shown in FIG. 9A, the pair of the first semiconductor chip 31 and the first heat sink 21 and the pair of the second semiconductor chip 32 and the second heat sink 22 are arranged in an opposite manner from that of the first embodiment.

In this semiconductor device, the first wiring portion wiring layer 111 is disposed on the second sealing member 52 and connected to the first heat sink 21 through the first heat sink via 531a formed in the first and second sealing members 51 and 52. The first terminal portion 112 is provided by a part of the first wiring portion wiring layer 111.

The second wiring portion wiring layer 121 has a second wiring portion first wiring layer 121a disposed on the second sealing member 52 and at a position facing the first semiconductor chip 31, a position facing the portion of the first heat sink 21 adjacent to the second heat sink 22, a position facing the portion of the second heat sink 22 adjacent to the first heat sink 21, and a position facing the second semiconductor chip 32. The second wiring portion wiring layer 121 has a second wiring portion second wiring layer 121b disposed on the first sealing member 51 and at a position facing the third heat sink 23 and a position facing the portion of the first heat sink 21 adjacent to the third heat sink 23.

The second wiring portion second wiring layer 121b is connected to the second terminal portion 122 through a second wiring portion via 522a formed in the second sealing member 52. The second wiring portion second wiring layer 121b is connected to the second wiring portion first wiring layer 121a through the second wiring portion via 522a formed in the second sealing member 52. The second wiring portion first wiring layer 121a is connected to the first electrode 321 of the second semiconductor chip 32 through the second chip via 512a formed in the first and second sealing members 51 and 52.

Even when the first to third wiring portions 101 to 103 are arranged in the manner as described above, the circuit configuration shown in FIG. 3 can be realized, and the similar effects to those in the first embodiment can be achieved.

In the semiconductor device shown in FIG. 9C, the third wiring portion wiring layer 131 is disposed on the second sealing member 52. The third wiring portion wiring layer 131 is connected to the first electrode 311 of the first semiconductor chip 31 through the first chip via 511a formed in the first and second sealing members 51 and 52. Moreover, the third wiring portion wiring layer 131 is connected to the second heat sink 22 through the second heat sink via 513a formed in the first and second sealing members 51 and 52. In this semiconductor device, the third terminal portion 132 is provided by a part of the third wiring portion wiring layer 131.

The first wiring portion wiring layer 111 and the second wiring portion wiring layer 121 are disposed such that the first wiring portion wiring layer 111 is located on the first sealing member 51 and the second wiring portion wiring layer 121 is located on the second sealing member 52. The first wiring portion wiring layer 111 is connected to the first heat sink 21 through the first heat sink via 531a formed in the first sealing member 51. The first wiring portion wiring layer 111 is connected to the first terminal portion 112 through the first wiring portion via 521a formed in the second sealing member 52.

The second wiring portion wiring layer 121 is connected to the first electrode 321 of the second semiconductor chip 32 through the second chip via 512a formed in the first and second sealing members 51 and 52. In this semiconductor device, the second terminal portion 122 is provided by a part of the second wiring portion wiring layer 121.

Even when the first to third wiring portions 101 to 103 are arranged in the manner as described above, the circuit configuration shown in FIG. 3 can be realized, and the similar effects to those in the first embodiment can be achieved.

In each of the embodiments described above, it is not always necessary that the semiconductor device includes the external connection heat sink 10. The semiconductor device may be used by being arranged such that the first to fourth heat sinks 21 to 24 are thermally connected to a mounting member via an insulating member arranged on the mounting member side.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A semiconductor device comprising:
a first semiconductor chip and a second semiconductor chip each having a switching element;
a first heat sink on which the first semiconductor chip is disposed;
a second heat sink on which the second semiconductor chip is disposed;
a sealing member sealing the first semiconductor chip and the second semiconductor chip, the sealing member being made of a resin;
a first wiring portion connected to the first semiconductor chip;
a second wiring portion connected to the second semiconductor chip; and
a third wiring portion connecting the first semiconductor chip and the second semiconductor chip, wherein
the first semiconductor chip and the second semiconductor chip are configured to be controllable, allowing them to be turned on and off so that current flows in opposite directions in the first wiring portion and the second wiring portion,
the first wiring portion, the second wiring portion, and the third wiring portion are collectively disposed on a side opposite to the first heat sink and the second heat sink with respect to the first semiconductor chip and the second semiconductor chip, and
the first wiring portion and the second wiring portion have portions facing each other,
the semiconductor device further comprising:
a third heat sink and a fourth heat sink that are disposed on a side opposite to the first wiring portion, the second wiring portion and the third wiring portion with respect to the first semiconductor chip and the second semiconductor chip, wherein
the third heat sink is disposed to face the first wiring portion and the second wiring portion, and
the fourth heat sink is disposed to face the third wiring portion.

2. The semiconductor device according to claim 1, wherein
the first to fourth heat sinks have a same thickness.

3. The semiconductor device according to claim 1, wherein
the first wiring portion includes a first terminal portion disposed on the sealing member,
the second wiring portion includes a second terminal portion disposed on the sealing member,
the third wiring portion includes a third terminal portion disposed on the sealing member,
a direction along which the first semiconductor chip and the second semiconductor chip are arranged is referred to as an arrangement direction, and a direction in which the first semiconductor chip and the first heat sink are stacked is referred to as a stacking direction, and
the third terminal portion, the first semiconductor chip, the second semiconductor chip, the first terminal portion, and the second terminal portion are arranged in this order along the arrangement direction, when viewed in the stacking direction.

4. The semiconductor device according to claim 3, wherein
the first wiring portion and the third wiring portion are disposed to face each other in the stacking direction in a section located above the first heat sink,
the first wiring portion has a non-overlapping portion without overlapping with the third wiring portion in the section located above the first heat sink, and
the first wiring portion is connected to the first semiconductor chip via the non-overlapping portion being connected to the first heat sink.

5. The semiconductor device according to claim 4, wherein
the first wiring portion has a portion disposed on a side opposite to the third heat sink with respect to the second wiring portion,
the third wiring portion is connected to the second semiconductor chip as being connected to the second heat sink, and is connected to a portion of the first semiconductor chip on a side opposite to the first heat sink, and
the second wiring portion is connected to a portion of the second semiconductor chip on a side opposite to the second heat sink.
